(19) United States
(12) Patent Application Publication
(10) Pub. No.: US 2026/0059915 A1
(43) Pub. Date: Feb. 26, 2026

(54) DISPLAY PANEL AND DISPLAY DEVICE

(71) Applicant: Tianma Advanced Display Technology Institute (Xiamen) Co.,Ltd., Xiamen (CN)

(72) Inventor: Peixuan CHEN, Xiamen (CN)

(21) Appl. No.: 18/758,791

(22) Filed: Jun. 28, 2024

(30) Foreign Application Priority Data
Mar. 26, 2024 (CN) 202410353385.3

(51) Int. Cl. H10H 29/49; H10H 29/32

(52) U.S. Cl. CPC H10H 29/49; H10H 29/32

(57) ABSTRACT

A display panel and a display device are provided. The display panel includes a display area and a signal detection module. The display area includes a plurality of pixel areas. One pixel area includes at least one pixel and a monitoring unit. The monitoring unit includes a conductive unit. The conductive unit includes a low-temperature polysilicon material; and/or the monitoring unit includes a first driving circuit. The first driving circuit includes at least one low-temperature polysilicon transistor. The signal detection module is used to detect a signal on at least one terminal of the monitoring unit.

### CROSS-REFERENCE TO RELATED APPLICATION

This application claims the priority of Chinese Patent Application No. 202410353385.3, filed on Mar. 26, 2024, the content of which is incorporated herein by reference in its entirety.

### TECHNICAL FIELD

The present disclosure generally relates to the field of display technology and, more particularly, relates to a display panel and a display device.

### BACKGROUND

From the cathode ray tube (CRT) era, the liquid crystal display (LCD,) era, to the current organic light-emitting diode (OLED) era and the light-emitting diode display era, the display industry has experienced rapid development over the past few decades. The display industry has been closely related to our lives. From traditional mobile phones, tablets, TVs, and PCs to current electronic devices such as smart wearable devices, VR, and car displays, display technology is inseparable.

Display products are prone to the problem of screen temperature rising during operation. When the screen temperature rises, serious color shift will appear in the display, affecting the display effect. If the screen temperature can be effectively monitored, display compensation can be performed based on temperature changes. However, how to effectively monitor the screen temperature of the display products is one of the technical bottlenecks faced at this phase.

### SUMMARY

One aspect of the present disclosure provides a display panel. The display panel includes: a display area and a signal detection module. The display area includes a plurality of pixel areas. One pixel area includes at least one pixel and a monitoring unit. The monitoring unit includes a conductive unit. The conductive unit includes a low-temperature polysilicon material; and/or the monitoring unit includes a first driving circuit. The first driving circuit includes at least one low-temperature polysilicon transistor. The signal detection module is used to detect a signal on at least one terminal of the monitoring unit.

Another aspect of the present disclosure provides a display device. The display device includes a display panel. The display panel includes a display area and a signal detection module. The display area includes a plurality of pixel areas. One pixel area includes at least one pixel and a monitoring unit. The monitoring unit includes a conductive unit. The conductive unit includes a low-temperature polysilicon material; and/or the monitoring unit includes a first driving circuit. The first driving circuit includes at least one low-temperature polysilicon transistor. The signal detection module is used to detect a signal on at least one terminal of the monitoring unit.

Other aspects or embodiments of the present disclosure can be understood by those skilled in the art in light of the description, the claims, and the drawings of the present disclosure.

### BRIEF DESCRIPTION OF THE DRAWINGS

The following drawings are merely examples for illustrative purposes according to various disclosed embodiments and are not intended to limit the scope of the present disclosure.

FIG. 1 illustrates a planar schematic diagram of an exemplary display panel consistent with various disclosed embodiments in the present disclosure;

FIG. 2 illustrates a relative position relationship of a signal detection module, pixels, and a monitoring unit in a pixel area consistent with various disclosed embodiments in the present disclosure;

FIG. 3 illustrates a structure of an exemplary monitor unit in a display pane consistent with various disclosed embodiments in the present disclosure;

FIG. 4 illustrates a structure of another exemplary monitoring unit in a display panel consistent with various disclosed embodiments in the present disclosure;

FIG. 5 illustrates a structure of another exemplary monitoring unit in a display panel consistent with various disclosed embodiments in the present disclosure;

FIG. 6 illustrates a connection structure of a first driving circuit in a display panel consistent with various disclosed embodiments in the present disclosure;

FIG. 7 illustrates a connection structure of a first driving circuit and a control chip;

FIG. 8 illustrates a ratio diagram of driving current at high temperature and normal temperature;

FIG. 9 illustrates an exemplary pixel driving circuit consistent with various disclosed embodiments in the present disclosure;

FIG. 10 illustrates a connection of a pixel driving circuit and a conducting unit;

FIG. 11 illustrates an exemplary arrangement of monitor circuits consistent with various disclosed embodiments in the present disclosure;

FIG. 12 illustrates another exemplary arrangement of monitor circuits consistent with various disclosed embodiments in the present disclosure

FIG. 13 illustrates an exemplary arrangement of monitor circuits when the display panel is a transparent display panel consistent with various disclosed embodiments in the present disclosure;

FIG. 14 illustrates another exemplary arrangement of monitor circuits when the display panel is a transparent display panel consistent with various disclosed embodiments in the present disclosure;

FIG. 15 illustrates another exemplary arrangement of monitor circuits when the display panel is a transparent display panel consistent with various disclosed embodiments in the present disclosure;

FIG. 16 illustrates a cross-sectional view of an exemplary display device consistent with various disclosed embodiments in the present disclosure;

FIG. 17 illustrates another cross-sectional view of an exemplary display device consistent with various disclosed embodiments in the present disclosure.

FIG. 18 illustrates a timing diagram of a pixel driving circuit and a first driving circuit consistent with various disclosed embodiments in the present disclosure; and

FIG. 19 illustrates an exemplary display device consistent with various disclosed embodiments in the present disclosure.

### DETAILED DESCRIPTION

Reference will now be made in detail to exemplary embodiments of the disclosure, which are illustrated in the accompanying drawings. Hereinafter, embodiments consistent with the disclosure will be described with reference to drawings. In the drawings, the shape and size may be exaggerated, distorted, or simplified for clarity. Wherever possible, the same reference numbers will be used throughout the drawings to refer to the same or like parts, and a detailed description thereof may be omitted.

Further, in the present disclosure, the disclosed embodiments and the features of the disclosed embodiments may be combined under conditions without conflicts. It is apparent that the described embodiments are some but not all of the embodiments of the present disclosure. Based on the disclosed embodiments, persons of ordinary skill in the art may derive other embodiments consistent with the present disclosure, all of which are within the scope of the present disclosure.

Moreover, the present disclosure is described with reference to schematic diagrams. For the convenience of descriptions of the embodiments, the cross-sectional views illustrating the device structures may not follow the common proportion and may be partially exaggerated. Besides, those schematic diagrams are merely examples, and not intended to limit the scope of the disclosure. Furthermore, a three-dimensional (3D) size including length, width, and depth should be considered during practical fabrication.

In the present disclosure, relational terms such as first and second are only used to distinguish one entity or operation from another entity or operation, and do not necessarily require or imply any such actual relationship between these entities or operations or order.

Moreover, the terms “including”, “comprising” or any other variants thereof are intended to cover non-exclusive inclusion, such that a process, method, article, or device that includes a series of elements includes not only those elements, but also those that are not explicitly listed or also include elements inherent to this process, method, article or equipment. If there are no more restrictions, the elements defined by the sentence “including . . . ” do not exclude the existence of other same elements in the process, method, article, or equipment that includes the elements.

It should be understood that when describing the structure of a component, when a layer or region is referred to as being “on” or “above” another layer or another region, the layer or region may be directly on another layer or region, or indirectly on another layer or region, for example, layers/components between the layer or region and another layer or another region. And, for example, when the component is reversed, the layer or region may be “below” or “under” another layer or region. In the present disclosure, the term “electrical connection” refers to that two components are directly electrically connected with each other, or the two components are electrically connected via one or more other components.

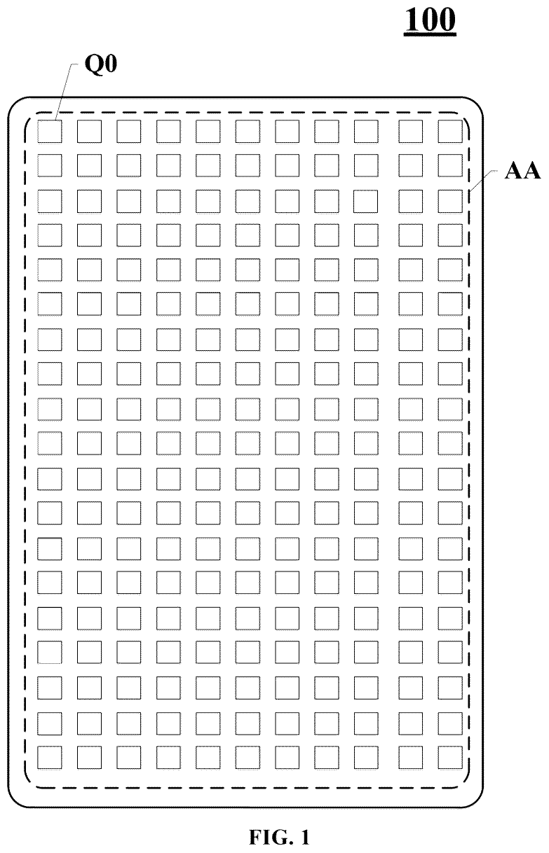

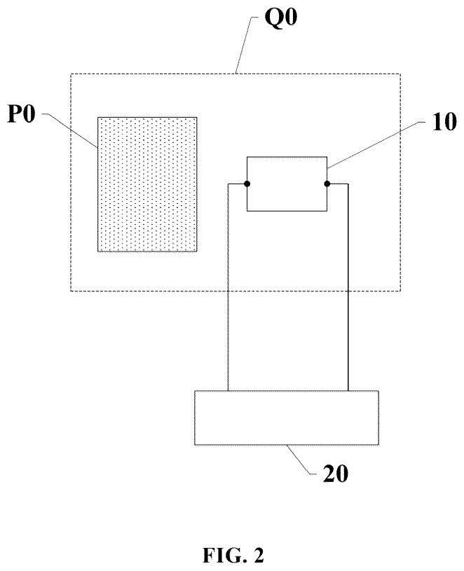

The present disclosure provides a display panel. As shown in FIG. 1 which is a planar diagram of an exemplary display panel provided by the present disclosure and FIG. 2 which is a relative position relationship of a signal detection module, pixels and a monitoring unit in a pixel area, in one embodiment, the display panel 100 may include a display region AA. The display region AA may include a plurality of pixel areas Q0. Each pixel area Q0 of the plurality of pixel areas Q0 may include at least one pixel. The pixel area Q0 may also include a monitoring unit 10.

The monitoring unit 10 may include a conductive unit 12 that is made of a material including a low-temperature polysilicon material; and/or

the monitoring unit 10 may include a first driving circuit 11 that includes at least one low-temperature polysilicon transistor.

The display panel may further include a signal detection module 20 and the signal detection module 20 may be used to detect the signal on at least one terminal of the monitoring unit 10.

The embodiment shown in FIG. 1 where the display panel has a rounded rectangular structure is used as an example only for illustration, and does not limit the actual shape of the display panel and the scope of the present disclosure. Also, the arrangement of the plurality of pixel areas Q0 in the display panel shown in FIG. 1 is used as an example only for illustration, and does not limit the scope of the present disclosure. The number, shape and arrangement relationship of the plurality of pixel areas Q0 actually included in the display panel may have any other suitable configuration, which is not limited in the present disclosure. The embodiment shown in FIG. 2 where each pixel area Q0 includes one pixel is used as an example only for illustration, and does not limit the number and shape of pixels actually included in one pixel area Q0 and the scope of the present disclosure. In some other embodiments, the number of pixels included in the pixel area Q0 may be two or more.

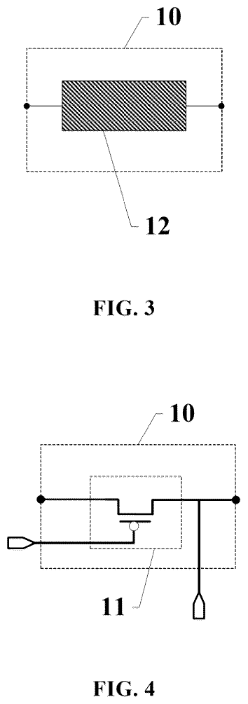

As shown in FIG. 1 and FIG. 2, in one embodiment, the monitoring unit 10 may be disposed in the pixel area Q0. There may be three different implementations of the monitoring unit 10. In one embodiment, as shown in FIG. 3, the monitoring unit 10 may only include one conductive unit 12 and the conductive unit 12 may be made of a material including low-temperature polysilicon. The conductive unit 12 may obtain an electrical signal through a control chip in the display panel. For example, a fixed current signal may be provided to the conductive unit 12 through the control chip. In another embodiment shown in FIG. 4, the monitoring unit 10 may only include a first driving circuit 11. The first driving circuit 11 may include at least one low-temperature polysilicon transistor. The first driving circuit 11 may be connected to the control chip in the display panel to obtain the electrical signal. For example, when one transistor in the first driving circuit 11 is turned on, the control chip may provide a fixed current signal to the transistor. In yet another embodiment, the monitoring unit 10 may include one aforementioned conductive unit 12 and one first driving circuit 11 at the same time. The conductive unit 12 may be connected to the first driving circuit 11 and obtain electrical signals through the first driving circuit 11. The first driving circuit 11 may obtain the signal through the control chip. For example, the control chip may control the transistor in the first driving circuit 11 to conduct and transmit the current signal to the conductive unit 10. In the embodiments shown in FIG. 3 to FIG. 5 respectively illustrating three structural schematic diagrams of the monitoring unit 10 in the display panel, the monitoring unit 10 may all include devices made of low-temperature polysilicon. The resistivity of low-temperature polysilicon changes with temperature. By disposing the monitoring unit 10 in the pixel area Q0, when the temperature in the pixel area Q0 changes, the current or voltage corresponding to the low-temperature polysilicon may also change with the temperature. Therefore, when the signal detection module 20 detects the signal from at least one terminal of the monitoring unit 10 in the pixel area Q0, the temperature change in the pixel area Q0 may be determined based on the change in the detected signal, thereby realizing effective monitoring of screen temperature of the display panel. Further, by disposing the monitoring unit 10 in the pixel area Q0, temperature monitoring at the pixel area level may be achieved, which is beneficial to achieving refined monitoring of the temperature in the display panel. When the temperature of the display screen is effectively monitored, the display data may be adjusted according to the temperature changes to avoid abnormal display problems such as color shift or uneven brightness because of temperature changes on the display panel, which is beneficial to improving the overall display effect of the display panel.

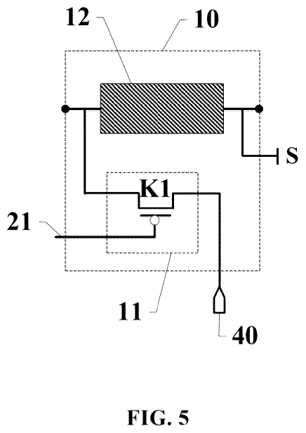

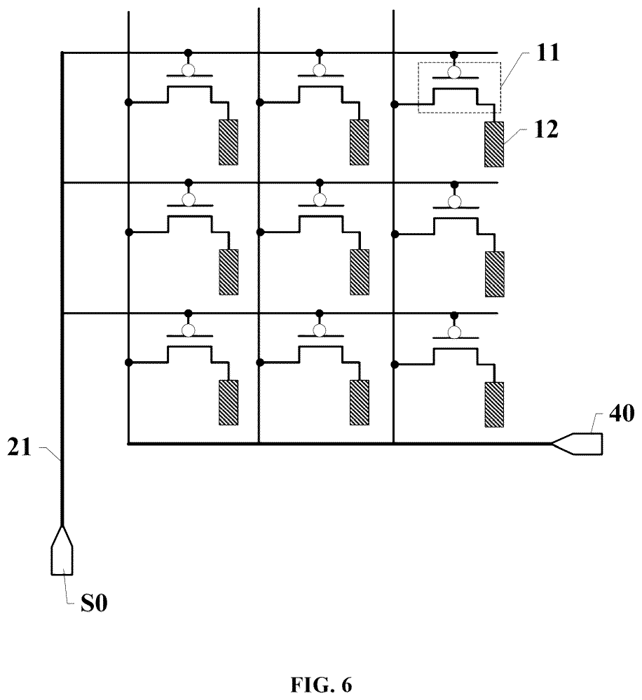

In one embodiment shown in FIG. 1 and FIG. 5, the monitoring unit 10 may include a conductive unit 12 and a first driving circuit 11. One terminal of the conductive unit 12 may be connected to the first driving circuit 11, and another terminal of the conductive unit 12 may be connected to a fixed voltage signal terminal S. The signal detection module 20 may detect the voltage or current at two terminals of the conductive unit 12.

In the present embodiment shows, the monitoring unit 10 may include the conductive unit 12 and the first driving circuit 11, and the conductive unit 12 and the first driving circuit 11 may have the connection relationship shown in FIG. 5. An output terminal of the first driving circuit 11 may be connected to one terminal of the conductive unit 12. Another terminal of the conductive unit 12 may receive a fixed voltage signal, for example, may be grounded. In one embodiment, in the monitoring unit 10, the conductive unit 12 may include a low-temperature polysilicon material, and the first driving circuit 11 may not include a low-temperature polysilicon transistor. When a fixed drive current is provided to the conductive unit 12 through the first driving circuit 11, and the temperature of the pixel area Q0 where the conductive unit 12 is located rises abnormally, the resistivity of the conductive unit 12 itself may also change, such that the voltage at two terminals of the conductive unit 12 may change. The signal detection module 20 may be configured to detect the change in the voltage at the two terminals of the conductive unit 12, such that the temperature change of the pixel area Q0 may be determined.

In another embodiment, in the monitoring unit 10, the conductive unit 12 may not include a low-temperature polysilicon material, and the first driving circuit 11 may include a low-temperature polysilicon transistor. When the temperature of the pixel area Q0 where the conductive unit 12 is located rises abnormally, the driving current output by the first driving circuit 11 to the conductive unit 12 may change with the change of temperature. The voltage at the two terminals of the conductive unit 12 may also change. The signal detection module 20 may be configured to detect the change in the voltage at the two terminals of the conductive unit 12, such that the temperature change of the pixel area Q0 may be determined.

In another embodiment, in the monitoring unit 10, the conductive unit 12 may include a low-temperature polysilicon material, and the first driving circuit 11 may include a low-temperature polysilicon transistor. When the temperature of the pixel area Q0 where the conductive unit 12 is located rises abnormally, the resistivity of the conductive unit 12 and the driving current output by the first driving circuit 11 to the conductive unit 12 may change with the change of temperature. A calibration test may be performed to test the corresponding relationship between the voltage change of the conductive unit 12 and the temperature. The signal detection module 20 may be configured to detect the change in the voltage at two terminals of the conductive unit 12 and the temperature corresponding to the voltage may be determined according to the result of the calibration test, such that the temperature change of the pixel area Q0 may be determined.

In one embodiment shown in FIG. 5, the first driving circuit 11 may include a switch transistor K1. The switch transistor K1 may be a low-temperature polysilicon transistor. In the switch transistor K1, a gate may be electrically connected to a first control line 21, a first electrode may be electrically connected to a first data terminal 40, and a second electrode may be electrically connected to the conductive unit 12.

In the present embodiment, the monitoring unit 10 may include both the first driving circuit 11 and the conductive unit 12. The first driving circuit 11 and the conductive unit 12 may be connected as shown in FIG. 5. The first driving circuit 11 may only include one switch transistor K1, and the switch transistor K1 may be turned on or off under the control of the control signal provided by the first control line 21. Two electrodes of the switch transistor K1 may be electrically connected to the first data terminal 40 and the conductive unit 12 respectively. When the temperature of the pixel area Q0 needs to be monitored, a control signal may be transmitted to the switch transistor K1 through the first control line 21 to turn on the switch transistor K1, such that the signal from the first data terminal 40 may pass through the switch transistor K1 which is turned on and may be transmitted to the conductive unit 12. Since the switch transistor K1 is a low-temperature polysilicon transistor, when the temperature of the pixel area Q0 where the first driving circuit 11 is located changes, the driving current output by the switch transistor K1 to the conductive unit 12 may change with the change of temperature.

The voltage across two terminals of the conductive unit 12 may also change as the drive current changes. By detecting the change of the voltage across the conductive unit 12 by the signal detection module 20, the temperature change of the pixel area Q0 where the first driving circuit 11 is located may be determined. Moreover, the first driving circuit 11 in this embodiment may only include one switch transistor K1, which does not require the introduction of complex circuit design. Therefore, the structure of the first driving circuit 11 may be simplified, and also the space occupied by the first driving circuit 11 on the display panel may be reduced, improving the overall screen-to-body ratio of the display panel.

FIG. 6 shows a schematic connection diagram of first driving circuits 11 in the display panel. As shown in FIG. 6, in one embodiment, gates of switch transistors K1 in a plurality of first driving circuits 11 in the display panel may be all electrically connected to the same first control line 21, and first electrodes of the switch transistors K1 in the plurality of first driving circuits 11 in the display panel may be all connected to the same first data terminal 40.

The plurality of first driving circuits 11 may be disposed in the plurality of pixel areas Q0 in the display panel. In one embodiment, a gate of a switch transistor K1 of each of the plurality of first driving circuits 11 may be electrically connected to the same first control line 21. Therefore, the switch transistor K1 of each of the plurality of first driving circuits 11 may be controlled to be turned on or off through one first control line 21. When temperature monitoring is required, the control signal may be transmitted through the first control line 21 to control all switch transistors K1 to be turned on at the same time, and there may be no need to set up different first control lines 21 for different first driving circuits 11. In one embodiment, the first control line 21 may be connected to the signal terminal of the control chip in the display panel. When only one first control line 21 is introduced for all of the plurality of first driving circuits 11, only one signal terminal may be required on the control chip to connect with the first control line 21. Therefore, the structure of the control chip may be simplified. In addition, in this embodiment, the first terminal of the switch transistor K1 in each first driving circuit 11 may be connected to the same first data terminal 40, and there may be no need to introduce different data terminals 40 for different first driving circuits 11. In one embodiment, the first data terminal 40 may be connected to the signal terminal of the control chip in the display panel. Therefore, by introducing one first data terminal 40 for all of the plurality of first driving circuits 11, the structure of the control chip may be simplified.

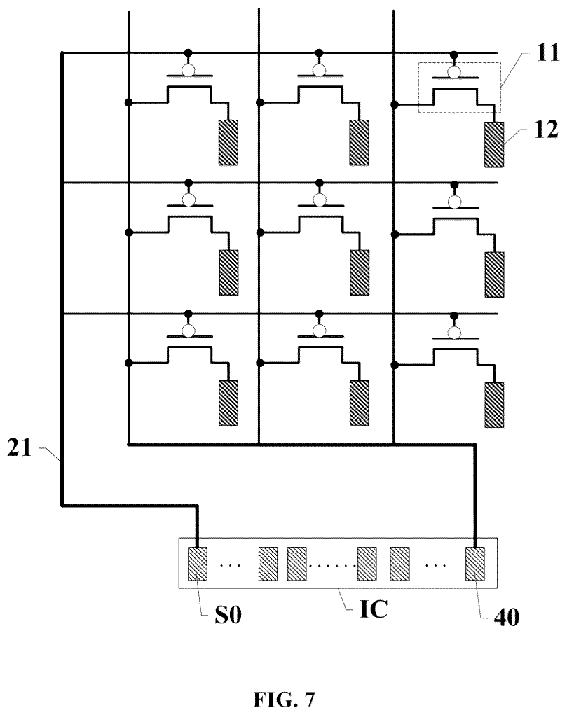

FIG. 7 shows a connection between the plurality of first driving circuits 11 and the control chip IC. In one embodiment shown in FIG. 7, the display panel may further include a control chip IC, and the plurality of first driving circuits 11 may be also connected to the control chip IC. For example, the first electrodes of the switch transistors K1 of the plurality of first driving circuits 11 may be connected to a first data terminal 40 of the control chip IC. The control chip IC may transmit a fixed current signal to the plurality of first driving circuits 11. The value of the fixed current signal may be I, where I≤0.1 μA.

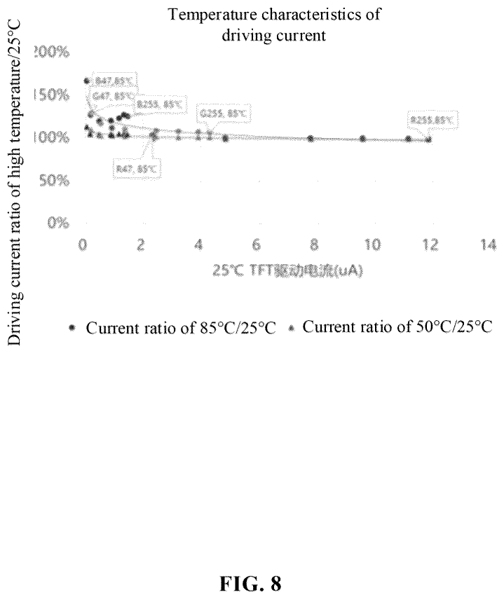

FIG. 8 shows a diagram of a ratio between driving current under high temperature and normal temperature, which includes a ratio between driving current at 85° C. and room temperature 25° C., and a ratio between driving current at 50° C. and room temperature 25° C., of the red pixel R, green pixel G, and blue pixel B. The current ratio between high temperature and room temperature may increase as the driving current at room temperature decreases. As the temperature rises, the current ratio between high temperature and room temperature may also increase under the same photocurrent. Further, when a small current is used for driving, the current ratio between high temperature and room temperature may be large. When the current is smaller, the corresponding ratio may be larger and it may be easier to detect the temperature change. Therefore, in this embodiment, when the current transmitted by the control chip IC to the first driving circuit 11 is set to I≤0.1 μA, the aforementioned current ratio may be larger, which is more conducive to monitoring the voltage change at two terminals of the conductive unit 12, and thus more conducive to improving the temperature detection accuracy.

As shown in FIG. 7, in one embodiment, the resistance of the conductive unit 12 may be R1, where 10 mΩ≤R1≤10000 mΩ. When the resistance of the conductive unit 12 is too large, the voltage change at two terminals of the conductive unit 12 may be relatively weak if only a small current is provided to the conductive unit 12. When the resistance of the conductive unit 12 is set at 10 mΩ˜10000 mΩ and a current less than or equal to 0.1 μA is provided to the conductive unit 12, the voltage across the conductive unit 12 may change significantly with the temperature change, which is more conducive to improving the accuracy of temperature monitoring.

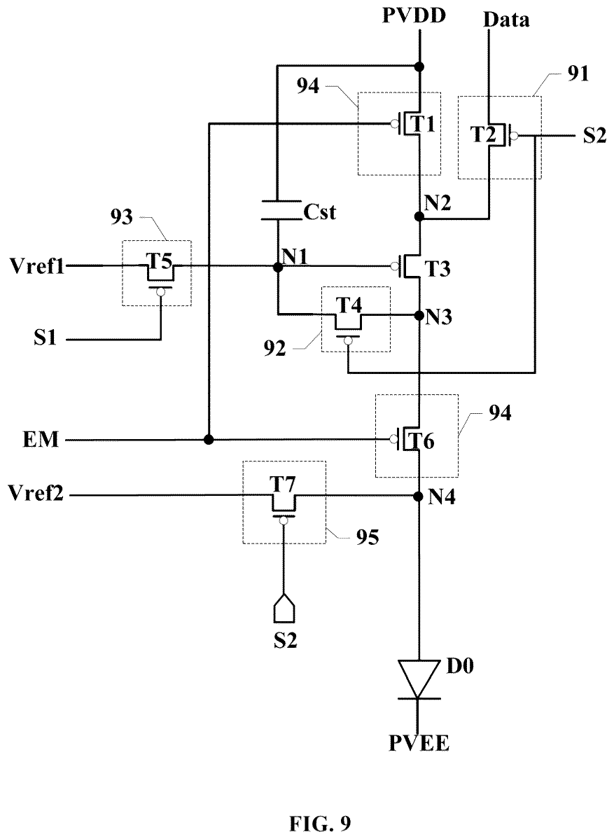

In one embodiment, a pixel driving circuit may be disposed in the pixel area Q0, which may be used to drive the pixels in the display panel to perform the display function. The pixel driving circuit may generate heat during operation, resulting in increasing screen temperature of the display panel. FIG. 9 shows a schematic diagram of a structure of a pixel driving circuit provided by the present disclosure. The embodiment with the pixel driving circuit shown in FIG. 9 may be used as an example only for illustration and does not limit the structure of the actual pixel driving circuit in the display panel. In one embodiment, as shown in FIG. 9, the pixel driving circuit may include a driving transistor T3, a data writing module 91, a compensation module 92, a first reset module 93, a light-emitting control module 94, and a second reset module 95. For the driving transistor T3, a gate of may be connected to a first node N1, a first electrode may be connected to a second node N2, and a second electrode may be connected to a third node N3. The data writing module 91 may include a second transistor T2,the light-emitting control module 94 may include a first transistor T1 and a sixth transistor T5, the compensation module 92 may include a fourth transistor T4, the first reset module 93 may include a fifth transistor T5, and the second reset module 95 may include a seventh transistor T7. Two electrodes of the fifth transistor T5 in the first reset module 93 may be respectively connected to a first reset signal line Vref1 and the first node N1, and a gate of the fifth transistor T5 in the first reset module 93 may be connected to a first scan line S1. Two electrodes of the second transistor T2 in the data writing module 91 may be respectively connected to a data line Data and the second node N2, and a gate of the second transistor T2 in the data writing module 91 and a gate of the fourth transistor T4 in the compensation module 92 may be connected to the second scan line S2. Two electrodes of the seventh transistor T7 in the second reset module 95 may be respectively connected to the second reset signal line Vref2 and the fourth node N4, and a gate of the seventh transistor T7 may be connected to the second scan line S2. Two electrodes of the first transistor T1 in the light control module 94 may be respectively connected to the first power signal line PVDD and the second node N2, and the gate may be connected to the light control signal line EM. The fourth node N4 may be connected to the anode of the light-emitting element D0, and the cathode of the light-emitting element D0 may be connected to the second power signal line PVEE. It should be noted that, the present embodiment where each transistor is described as a P-type transistor in the pixel driving circuit provided in this embodiment is used as an example only to illustrate the present disclosure, and does not limit the scope of the present disclosure. In various embodiments, the type of the transistors may not be limited. For example, in some other embodiments, at least some of the transistors in the pixel driving circuit may also be embodied as N-type transistors. The pixel driving circuit in this embodiment may be used as an example only for illustration, and the actual structure and connection relationship of the pixel driving circuit are not limited. The working timing of the pixel driving circuit will be described in subsequent embodiments.

The pixel in the pixel area Q0 is driven by the corresponding pixel driving circuit. Optionally, at least one of the first transistor T1 to the seventh transistor T7 in the above-mentioned driving circuit may be embodied as a low-temperature polysilicon transistor. In one embodiment, at least one low-temperature polysilicon transistor in the first driving circuit 11 may multiplex the transistor in the pixel driving circuit. Therefore, there may be no need to introduce a new low-temperature polysilicon transistor for the first driving circuit 11 and the low-temperature polysilicon transistor in the pixel driving circuit may be multiplexed. The overall structure of the display panel may be simplified.

Optionally, in one embodiment, when the pixel driving circuit itself includes a low-temperature polysilicon transistor, the pixel driving circuit as a whole may be multiplexed as the first driving circuit 11. When the temperature in the pixel area Q0 where the pixel driving circuit is located changes, the output current of the pixel driving circuit may also change with the change of temperature. By monitoring the output current of the pixel driving circuit through the signal detection module 20, the temperature change of the pixel area Q0 may be determined.

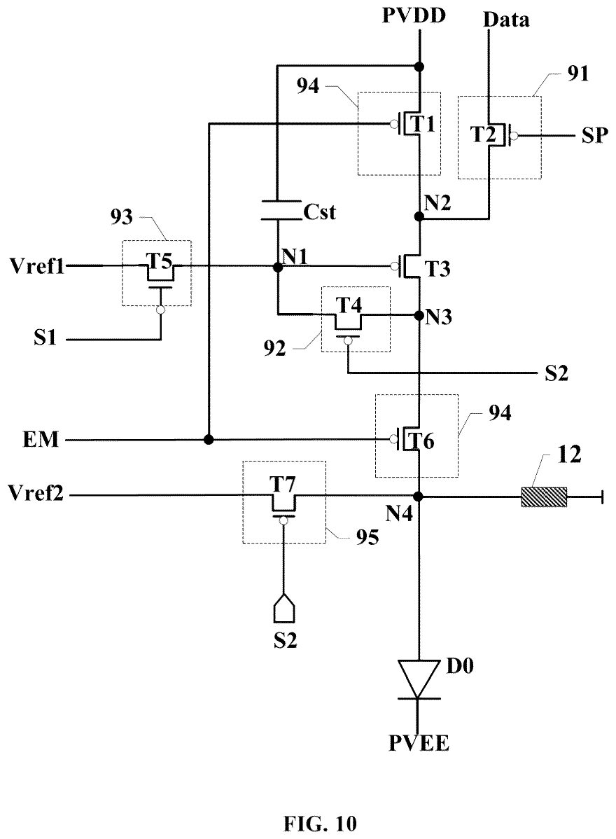

Therefore, there may be no need to introduce a new first driving circuit 11 in the display panel, and the structure of the display panel may be simplified. When the pixel driving circuit is multiplexed as the first driving circuit 11 in the monitoring unit 10, the monitoring unit 10 may further include a conductive unit 12 connected to the pixel driving circuit. For example, as shown in FIG. 10 which is a schematic diagram of a connection between the pixel driving circuit and the conductive unit 12. In one embodiment shown in FIG. 10, the temperature change in the pixel area Q0 may also be determined by detecting the change in the voltage across the conductive unit 12 by the signal detection unit. The resistance of the conductive unit 12 may also be set to 10 mΩ≤R1≤10000 mΩ, and the current output by the pixel driving circuit to the conductive unit 12 may also be set to I≤0.1 μA.

In one embodiment shown in FIG. 6 and FIG. 7, conductive units 12 may be disposed in the display panel. A maximum length of the orthographic projection of one conductive unit 12 on the plane where the display panel is located is D0, where 10 μm≤D0≤100 μm. When the size of the conductive unit 12 is large, it will be difficult to integrate the conductive unit 12 into the pixel area Q0. Taking the transparent display panel as an example, when the size of the conductive unit 12 is large, for example, for a common temperature microsensor in existing technologies having a size of above 700 μm, the space in the pixel area may be not enough to set the conductive unit 12. Further, the spacing between adjacent pixel areas in the transparent display panel is usually 100 μm to 250 μm. When the temperature microsensor in existing technologies is used as the conductive unit, the conductive unit may occupy a large space in the pixel area and the transparent area, which significantly affects the transmittance of the display panel. Therefore, when the maximum length of the conductive unit 12 is set to 10 μm to 100 μm in the embodiment, the size of the conductive unit 12 may be smaller than the size of the temperature microsensor in existing technologies, and the conductive unit 12 may be set in the pixel area Q0 without occupying the space of the transparent area Q1, thereby avoiding the influence on the transparency of the transparent display panel.

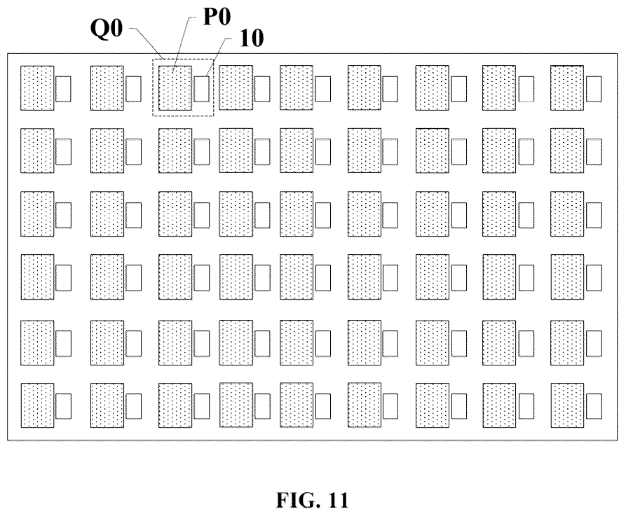

In one embodiment shown in FIG. 11 which is an arrangement diagram of monitoring units 10 in the display panel, the number of monitoring units 10 included in the display panel may be less than or equal to the number of pixels. When the monitoring units 10 are introduced into the display panel, one monitoring unit 10 may be disposed in an area corresponding to one pixel. At this time, the number of monitoring units 10 in the display panel may be equal to the number of the pixels, such that the abnormal may be able to be effectively detected when the temperature of the area corresponding to each pixel is abnormal. The accuracy of temperature detection may be improved.

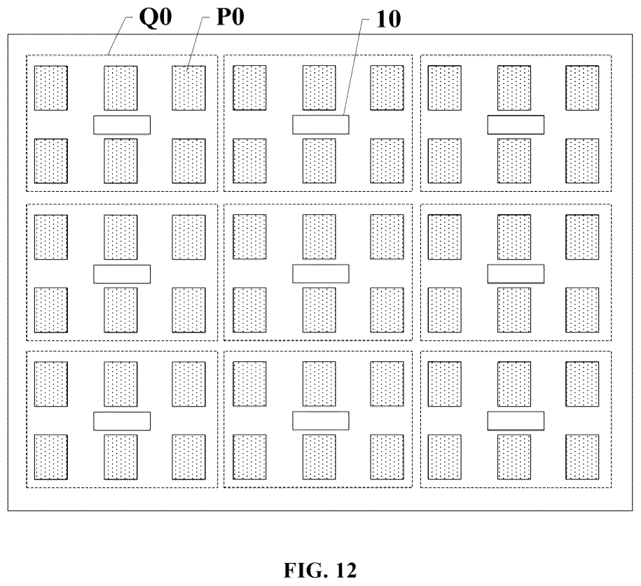

In another embodiment shown in FIG. 12 which is another arrangement diagram of monitoring units 10 in the display panel, the number of monitoring units 10 included in the display panel may be less than the number of the pixels. When the display panel includes a large number of pixels, the distance between the pixels may be small and the temperature changes in the areas corresponding to adjacent pixels may be the same or basically the same. Therefore, one monitoring unit 10 may be set in areas corresponding to multiple pixels. The temperature changes in the corresponding areas may be monitored by this monitoring unit 10. Therefore, while realizing the monitoring of the screen temperature of the display panel, the number of the monitoring units 10 included in the display panel and the space occupied by the monitoring units 10 in the display panel may be reduced, improving the screen-to-body ratio of the display panel.

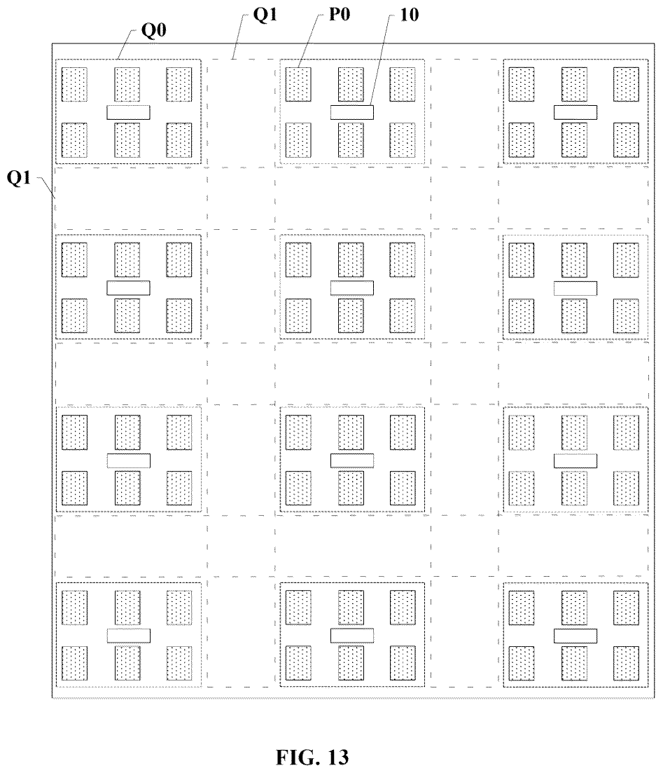

FIG. 13 shows an arrangement of the monitoring units 10 when the display panel is a transparent display panel. As shown in FIG. 13, in one embodiment, the display panel may further include a transparent area Q1 located between two adjacent pixel areas Q0, and each pixel area Q0 may include at least one pixel. Each pixel area Q0 may be also provided with a monitoring unit 10, or at least some pixel areas Q0 are not provided with monitoring units 10.

In the present embodiment, the display panel may be a transparent display panel. In the transparent display panel, adjacent pixel areas Q0 may be separated by the transparent area Q1, and the circuit structure and the like may be all arranged in the pixel areas Q0. One pixel area Q0 may include at least one pixel P0. In one embodiment shown in FIG. 13, the pixel area Q0 may include a plurality of pixels P0 and each pixel area Q0 may be provided with one monitoring unit 10. In the transparent display panel, the circuit structures such as the pixel driving circuits in the display area AA may be all arranged in the pixel areas Q0. Since the adjacent pixel areas Q0 are isolated by the transparent area Q1, the heat generated by the pixel driving circuits and the like may be concentrated in the pixel areas Q0. When the monitoring units 10 are arranged in the pixel areas Q0, the temperature change of the pixel areas Q0 may be monitored in a targeted manner. In one embodiment, one monitoring unit 10 may be arranged in each pixel area Q0, and the temperature of each pixel area Q0 may be effectively monitored. In some other embodiments, when the monitoring units 10 are set in the pixel areas Q0, the monitoring units 10 may not occupy the space of the light-transmitting areas Q1, and thus may not affect the transmittance of the transparent display panel.

The present embodiment with the number of pixels included in the pixel area Q0 is used as an example only for illustration, and does not limit the number of pixels actually included in the pixel area Q0 in the present disclosure.

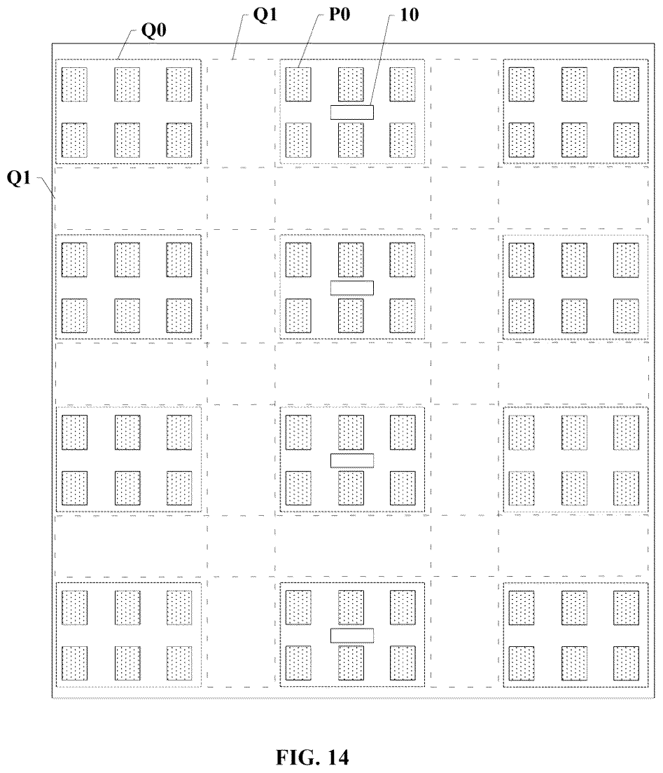

FIG. 14 shows an arrangement of the monitoring units 10 when the display panel is a transparent display panel. As shown in FIG. 14, in one embodiment, at least part of the plurality of pixel areas Q0 may be not provided with monitoring units 10, that is, the monitoring units 10 may be provided in part of the plurality of pixel areas Q0. Assuming that the plurality of pixel areas Q0 in the display panel are arranged in an array, the temperature changes of pixel areas Q0 in the same row may be basically the same. Therefore, one or several pixel areas Q0 in a row of pixel areas Q0 may be selected to accommodating the monitoring units 10. The average value of the signal values of several monitoring units 10 in the pixel areas Q0 of the corresponding row detected by the signal detection unit may be used as the judgment standard for the temperature change of the pixel areas Q0 in the row. The number of the monitoring units 10 actually included in the display panel may be reduced, simplifying the structural complexity of the display panel.

As shown in FIG. 11 to FIG. 13, in one embodiment, the monitoring units 10 may be evenly arranged in the display area AA. The even arrangement of the monitoring units 10 may enable the temperature of each partition of the display panel to be monitored, which is conducive to improving the comprehensiveness of temperature monitoring of each area of the display screen. For example, the even arrangement may be regarded as the same interval between two adjacent monitoring units 10 in the same row, the same interval between two adjacent monitoring units in the same column, or the even arrangement of the monitoring units 10 in the display area.

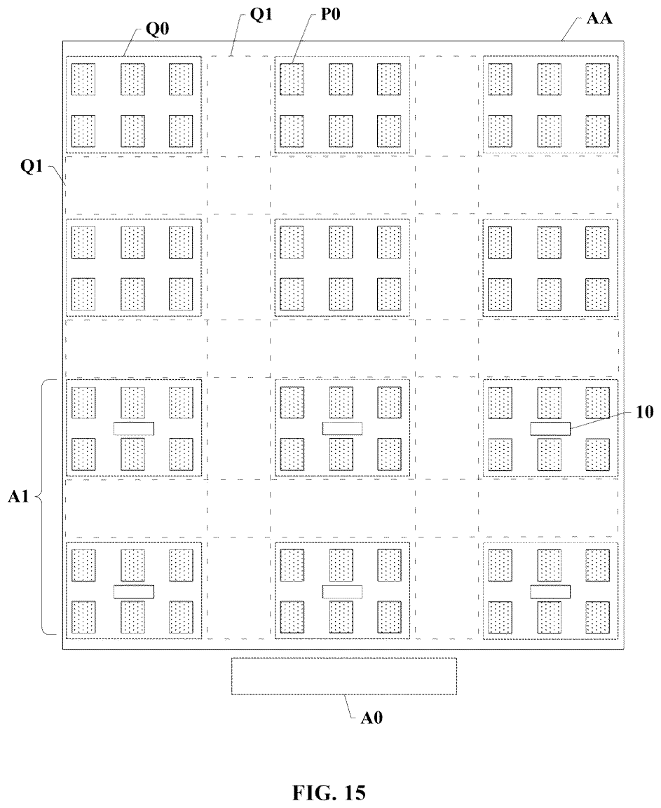

FIG. 15 shows an arrangement of the monitoring units 10 when the display panel is a transparent display panel. As shown in FIG. 15, in one embodiment, the display panel may include a bonding area A0 located on one side of the display area AA, and the bonding area A0 may be used to bond the control chip or the flexible circuit board. The display area AA may include a sub-display area A1 adjacent to the bonding area A0, and the area of the sub-display area A1 may be smaller than the area of the display area AA. The monitoring units 10 may be only arranged in the sub-display area A1.

In the present embodiment, the monitoring units 10 may be only arranged in the sub-display area A1 close to the bonding area A0. The area with higher temperature on the display screen may be mainly concentrated in the part of the display area AA close to the bonding area A0, and this part of the display area AA may be more likely to need chromaticity and brightness compensation due to temperature changes. Therefore, in this embodiment, the monitoring units 10 may be arranged in the sub-display area A1 adjacent to the bonding area A0, that is, targeted temperature monitoring may be performed for the area where high temperature may appear in the display panel, such that the chromaticity and brightness compensation of this part of the area may be performed timely when temperature abnormality occurs. There may be no need to set monitoring units for the area where temperature abnormality basically does not occur, thereby reducing the number of monitoring units 10 actually included in the display panel, which is conducive to simplifying the overall structure of the display panel.

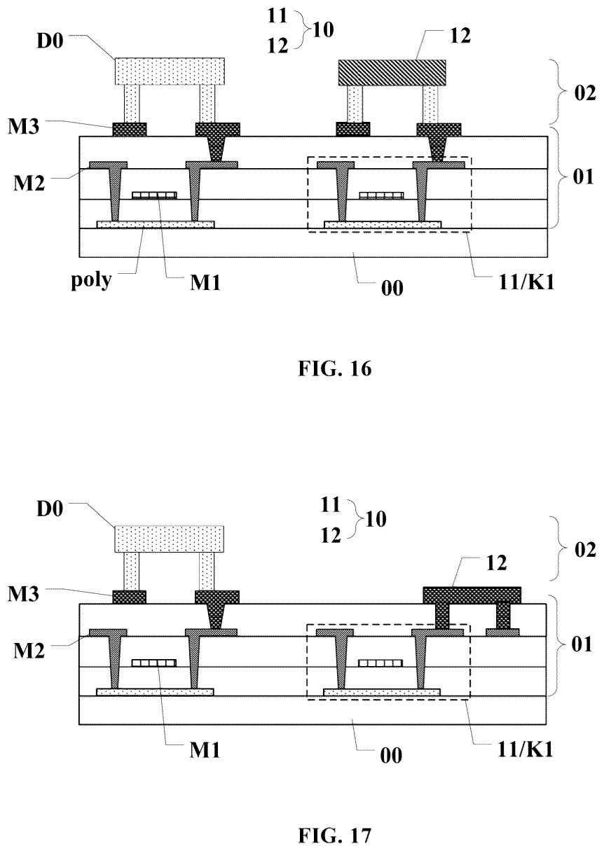

FIG. 16 shows a cross-sectional view of a display panel provided by the present disclosure, to illustrate a partial structure of the pixel driving circuit and the monitoring unit. In one embodiment shown in FIG. 16, the monitoring unit 10 may include the first driving circuit 11 and the conductive unit 12. The display panel may include a substrate 00, a driving layer 01 and a light-emitting layer 02 arranged on the same side of the substrate 00. The driving layer 01 may be located between the light-emitting layer 02 and the substrate 00. The pixel driving circuits may be disposed in the driving layer 01, and the light-emitting layer 02 may be provided with the light-emitting elements D0. The light-emitting elements D0 may be electrically connected to the pixel driving circuits. The monitoring unit 10 may be at least partially located in the driving layer 01. When the monitoring unit 10 is introduced into the display panel, the monitoring unit 10 may be at least partially arranged in the driving layer 01, and there may be no need to introduce a new film layer structure for the monitoring unit 10 in the display panel. The existing film layer structure of the display panel may be multiplexed, which is conducive to simplifying the overall film layer structure of the display panel when the monitoring unit 10 is introduced.

When the monitoring unit 10 includes a first driving circuit 11 and the transistors in the first driving circuit 11 multiplexed the transistors in the pixel driving circuit, since the transistors in the pixel driving circuit are located in the driving layer, the monitoring unit 10 may be considered at least partially located in the driving layer. When the monitoring unit 10 includes a conductive unit 12, the conductive unit 12 may also be arranged in the array layer to simplify the overall film layer structure of the display panel.

The cross-sectional view in FIG. 16 only shows a connection between a transistor in one pixel driving circuit and one corresponding light-emitting element D0, and does not limit the structure of the pixel driving circuit. In some embodiments, the light-emitting element D0 may be a Micro LED. The Micro LED is an LED with a grain size of about 1 μm-10 μm, which may be able to realize a display screen with pixel particles of 0.05 mm or smaller. The Micro LED has very low power consumption, good material stability and no image retention, and is particularly suitable for transparent display panels. Of course, in some other embodiments of the present disclosure, the light-emitting element D0 may also be a Mini LED or an organic electroluminescent element, and the present disclosure does not specifically limit this.

In one embodiment shown in FIG. 16, the first driving circuit 11 may be located in the driving layer 01, and the conductive unit 12 may be located on the side of the first driving circuit 11 away from the substrate. Along the direction perpendicular to the plane where the display panel is located, the conductive unit 12 and the light-emitting element D0 may not overlap.

When the monitoring unit 10 includes the first driving circuit 11 and the conductive unit 12 at the same time, the first driving circuit 11 may include at least one transistor, and the first driving circuit 11 may be set in the driving layer of the display panel without adding a new film layer in the display panel to accommodate the first driving circuit 11. Therefore, there may be no need to increase the film layers of the display panel, which is conducive to simplifying the film layer structure when the first driving circuit 11 is introduced into the display panel. The conductive unit 12 in the monitoring unit 10 may be disposed on the side of the first driving circuit 11 away from the substrate to facilitate the connection between the conductive unit 12 and the first driving circuit 11. Also, along the direction perpendicular to the plane where the substrate is located, the conductive unit 12 and the light-emitting element D0 may not overlap, and the introduction of the conductive unit 12 may be prevented from affecting the light output of the light-emitting element D0.

In one embodiment shown in FIG. 16, the conductive unit 12 may be disposed on the same layer as the light-emitting element D0. When the conductive unit 12 is disposed on the same layer as the light-emitting element D0, there may be no need to introduce a new film layer structure for the conductive unit 12, and the number of film layers of the display panel may not be increased, which is also conducive to simplifying the film layer structure of the display panel.

In one embodiment shown in FIG. 17 which is another cross-sectional view of the display panel, the conductive unit 12 may be located on the side of the light-emitting element D0 facing the first driving circuit 11. In the film layer structure of the conductive unit 12, the conductive unit 12 may be disposed on the side of the light-emitting element D0 facing the substrate, that is, the conductive unit 12 may be disposed in a film layer between the light-emitting element D0 and the transistors in the first driving circuit 11, such that the conductive unit 12 may be prevented from being set in the light-emitting direction of the light-emitting element D0 and from interfering with the emitted light of the light-emitting element D0.

In one embodiment, the array layer may include a first metal layer M1 and a second metal layer M2. The second metal layer M2 may be located on a side of the first metal layer M1 away from the substrate 00. The gate of the transistor may be located in the first metal layer M1, and the source and drain of the transistor may be located in the second metal layer M2. Optionally, the array layer 01 may further include a third metal layer M3 arranged on the side of the second metal layer M2 away from the substrate 00, and the third metal layer M3 may be used to accommodate some signal wires of the display panel, for example. When the conductive unit 12 is arranged on the side of the light-emitting element D0 facing the substrate, the conductive unit 12 may be disposed in the third metal layer M3. Therefore, there may be no need to introduce a new film layer structure for the conductive unit 12, and the number of film layers of the display panel may not be increased, which is also conducive to simplifying the film layer structure of the display panel.

As shown in FIG. 16, FIG. 17, and FIG. 9, in one embodiment, the pixel region Q0 may further include a light-emitting element D0 and a pixel driving circuit connected to the light-emitting element D0. The pixel driving circuit may include at least one low temperature polysilicon transistor, and the switch transistor K1 in the first driving circuit 11 may be manufactured simultaneously with the at least one low temperature polysilicon transistor in the pixel driving circuit.

When the first driving circuit 11 includes a low temperature polysilicon transistor, the low temperature polysilicon transistor in the first driving circuit 11 may be manufactured simultaneously with the at least one low temperature polysilicon transistor in the pixel driving circuit, and there may be no need to introduce an additional manufacturing process for the low temperature polysilicon transistor in the first driving circuit 11. The overall manufacturing process of the display panel when the first driving circuit 11 is introduced into the display panel may be simplified, improving the production efficiency of the display panel.

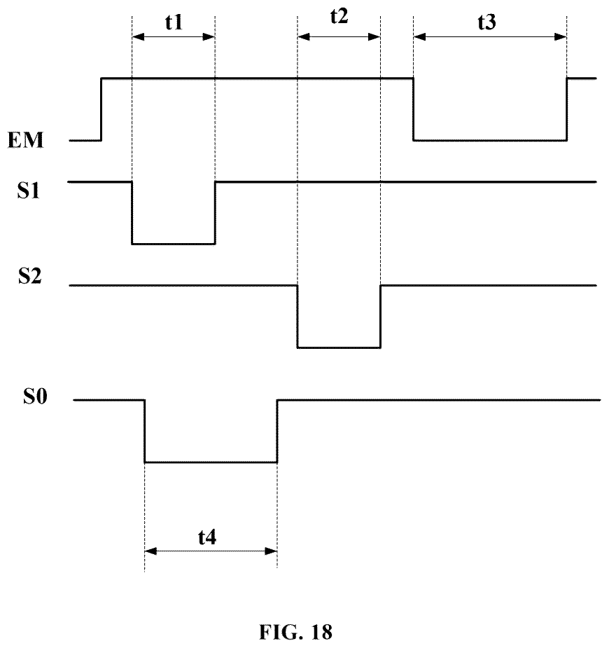

FIG. 18 shows a timing diagram of the pixel driving circuit and the first driving circuit 11. As shown in FIG. 6, FIG. 9, and FIG. 18, in one embodiment, the working phases of the pixel driving circuit may include a reset phase t1, a data writing phase t2, and a light-emitting phase t3. The working phases of the first driving circuit 11 may include a temperature monitoring phase t4, and the temperature monitoring phase t4 may not overlap with the light-emitting phase t3.

As shown in FIG. 9, for the pixel driving circuit, in the reset phase t1, the first scan line Scan1 may provide a low-level signal to the fifth transistor T5, the fifth transistor T5 may be turned on, such that the reset signal may be transmitted to the driving transistor T3 to reset the gate of the driving transistor T3. In the data writing phase t2, the second scan line S2 may provide a low-level signal to the second transistor T2, the fourth transistor T4, and the seventh transistor T7, the second transistor T2, the fourth transistor T4, and the seventh transistor T7 may be turned on, such that the data signal is written to the gate of the driving transistor T3 (that is, the threshold capture of the driving transistor T3) and the reset signal is transmitted to the fourth node N4 to reset the anode of the light-emitting element D0. In the light-emitting phase t3, the light-emitting control line EM may provide a low-level signal to the first transistor T1 and the sixth transistor T6, the first transistor T1 and the sixth transistor T6 may be turned on, such that the signal on the power signal line PVDD is transmitted to the driving transistor T3 and the light-emitting element D0 emits light in response to the driving signal of the driving transistor T3.

The light-emitting element D0 may generate light-induced leakage current in the light-emitting phase. When the temperature monitoring phase t4 of the first driving circuit 11 is set to be non-overlapping with the aforementioned light-emitting phase t3, temperature monitoring may not be performed in the light-emitting phase t3, which is conducive to preventing the light-induced leakage current in the light-emitting phase from affecting the driving characteristics of the first driving circuit 11 and thus is conducive to improving the accuracy of temperature monitoring. When the temperature monitoring phase does not overlap with the light-emitting phase, the temperature monitoring phase may be set to overlap with the reset phase or the data writing phase, and the present disclosure does not specifically limit this.

As shown in FIG. 2 and FIG. 7, in one embodiment, the display panel may further include a control chip IC, and the signal detection module 20 may be integrated in the control chip IC. Two terminals of the conductive unit 12 may be electrically connected to the signal detection module 20 through signal wirings. When the signal detection module 20 is integrated into the control chip IC, the signal change at the two terminals of the conductive unit 12 may be detected by the control chip IC, which is conducive to improving the integration of the display panel.

As shown in FIG. 2, FIG. 7, and FIG. 11 to FIG. 13, in one embodiment, the display panel may further include a control chip IC. When the signal detection module 20 detects that the voltage or current value at two terminals of the monitoring unit 10 exceeds a preset value, the control chip IC may adjust the data voltage provided to the pixel corresponding to the monitoring unit 10.

In the temperature monitoring stage, when it is detected that the voltage or current value at two terminals of the monitoring unit 10 exceeds the preset value, the temperature of the pixel area Q0 where the monitoring unit 10 is located may exceed the standard, and the chromaticity or brightness of the pixel area Q0 needs to be adjusted. At this time, the control chip IC may adjust the data voltage provided to the corresponding pixel area Q0 according to the temperature exceeding the standard, thereby achieving the adjustment of the chromaticity or brightness of the pixel area Q0 and improving the color deviation or brightness abnormality caused by high temperature. In one embodiment where the pixel area Q0 where the monitoring unit 10 is located has only one pixel P0, as shown in FIG. 11, when the voltage or current value at two terminals of the monitoring unit 10 exceeds the preset value, the data voltage of the pixel P0 in the pixel area Q0 where the monitoring unit 10 is located may be adjusted. In another embodiment shown in FIG. 12, the pixel area Q0 where the monitoring unit 10 is located may include a plurality of pixels P0. When the voltage or current value across the monitoring unit 10 exceeds the preset value, the data voltage of each pixel P0 in the pixel area Q0 where the monitoring unit 10 is located may be adjusted. For example, when the display panel is a transparent display panel shown in FIG. 13, the pixel areas Q0 may be separated by the light-transmitting areas Q1. When the voltage or current across the monitoring unit 10 in one certain pixel area Q0 exceeds the preset value, the data voltage received by the pixels P0 in the certain pixel area Q0 may need to be adjusted, that is, the overall color deviation or brightness of the certain pixel area Q0 may need to be adjusted. In some other embodiments, not every pixel area Q0 may be provided with one monitoring unit 10. As shown in FIG. 14, in one embodiment, a row of pixel areas Q0 may be provided with only one monitoring unit 10. When the voltage or current value across one certain monitoring unit 10 exceeds the preset value, the control chip IC may adjust the data voltage of all pixels P0 in one row of pixel areas Q0 where the certain monitoring unit 10 is located, to adjust the chromaticity and brightness of each pixel in the row of pixel areas Q0.

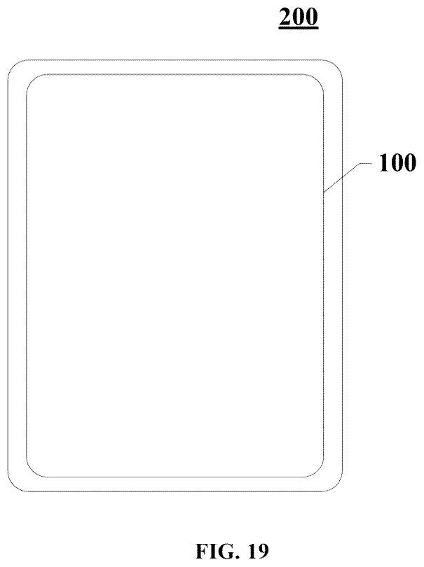

The present disclosure also provides a display device. In one embodiment shown in FIG. 19, the display device 200 may include a display panel 100 provided by various embodiments of the present disclosure. The display device provided by the present disclosure may have similar advantages as the display panel provided by various embodiments of the present disclosure.

The display device 200 provided by the various embodiments of the present disclosure may be a touch screen, a mobile phone, a tablet, a laptop computer, an E-ink paper, a television, or other devices with display functions. The type of the display device is not specifically limited in the present disclosure.

The embodiment in FIG. 19 where the display device 200 has a rounded-rectangle structure is used as an example only to illustrate the present disclosure, and does not limit the scope of the present disclosure. In some other embodiments, the display device 200 may have a rectangular, circular, oval, or any other suitable structure.

In the display panel and display device provided by the present disclosure, the monitoring unit and the signal detection module may be introduced. The monitoring unit may include a device made of a material including low-temperature polysilicon. The resistivity of low-temperature polysilicon changes with the change of temperature. In the present disclosure, the monitoring unit may be disposed in the pixel area. When the temperature in the pixel area changes, the current or voltage corresponding to the low-temperature polysilicon may also change with the change of temperature. Therefore, by detecting the signal on at least one terminal of the monitoring unit in the pixel area through the signal detection module, the temperature change in the pixel area may be determined based on the change of the detected signal, thereby realizing effective monitoring of the temperature of the display screen of the display panel. Further, by disposing the monitoring unit in the pixel area, temperature monitoring at the pixel area level may be achieved. Refined monitoring of the temperature in the display panel may be realized. When the temperature of the display screen is effectively monitored, the display data may be adjusted according to the temperature change, to avoid abnormal display problems such as color deviation or abnormal brightness of the display panel due to temperature changes. The overall display effect of the display panel may be improved.

In the present disclosure, relational terms such as “first” and “second” are only used to distinguish one entity or operation from another entity or operation, and do not necessarily require or imply that there is a relationship between these entities or operations. There is no such actual relationship or sequence. Furthermore, the terms “comprises”, “include”, or any other variations thereof are intended to cover a non-exclusive inclusion such that a process, method, article, or apparatus that includes a list of elements includes not only those elements, but also those not expressly listed, or elements inherent to the process, method, article or equipment. Without further limitation, an element defined by the statement “comprises a . . . ” does not exclude the presence of additional identical elements in a process, method, article, or apparatus that includes the stated element.

Various embodiments have been described to illustrate the operation principles and exemplary implementations. It should be understood by those skilled in the art that the present disclosure is not limited to the specific embodiments described herein and that various other obvious changes, rearrangements, and substitutions will occur to those skilled in the art without departing from the scope of the disclosure. Thus, while the present disclosure has been described in detail with reference to the above described embodiments, the present disclosure is not limited to the above described embodiments, but may be embodied in other equivalent forms without departing from the scope of the present disclosure, which is determined by the appended claims.

What is claimed is:

1. A display panel, comprising a display area and signal detection module, wherein:
the display area includes a plurality of pixel areas;
one pixel area of the plurality of pixel area includes at least one pixel and a monitoring unit;
the monitoring unit includes a conductive unit;
the conductive unit includes a low-temperature polysilicon material; and/or the monitoring unit includes a first driving circuit;
the first driving circuit includes at least one low-temperature polysilicon transistor; and
the signal detection module is used to detect a signal on at least one terminal of the monitoring unit.

2. The display panel according to claim 1, wherein:
the monitoring unit includes the conductive unit and the first driving circuit;
one terminal of the conductive unit is connected to the first driving circuit, and another terminal is connected to a fixed voltage signal terminal; and
the signal detection module is configured to detect the voltage or current at two terminals of the conductive unit.

3. The display panel according to claim 1, wherein:
the pixel area further includes a pixel driving circuit, and at least one low-temperature polysilicon transistor in the first driving circuit is multiplexed from a transistor in the pixel driving circuit.

4. The display panel according to claim 1, further including a control chip, wherein:
the first driving circuit is also connected to the control chip;
the control chip is used to transmit a fixed current signal to the first driving circuit; and
a current value of the current signal is I, wherein I≤0.1 μA.

5. The display panel according to claim 1, wherein:
resistance of the conductive unit is R1, wherein 10 mΩ≤R1≤10000 mΩ.

6. The display panel according to claim 1, wherein:
a maximum length of an orthographic projection of the single conductive unit on a plane where the display panel is located is D0, wherein 10 μm≤D0≤100 μm.

7. The display panel according to claim 1, wherein:
a number of monitoring units included in the display panel is less than or equal to a number of pixels.

8. The display panel according to claim 7, further including light-transmitting areas between adjacent pixel areas of the plurality of pixel areas, wherein:
each of the plurality of pixel areas is provided with one monitoring unit, or at least some of the plurality of pixel areas are not provided with monitoring units.

9. The display panel according to claim 7, wherein:
the monitoring units are evenly arranged in the display area.

10. The display panel according to claim 7, further including a bonding area at a side of the display area, wherein:
the bonding area is used to bond a control chip or a flexible circuit board;
the display area includes a sub-display area adjacent to the bonding area;
an area of the sub-display area is smaller than an area of the display area; and
the monitoring units are only arranged in the sub-display area.

11. The display panel according to claim 1, including a substrate, and a driving layer and a light-emitting layer, wherein:
the driving layer and the light-emitting layer are disposed at a same side of the substrate;
the driving layer is located between the light-emitting layer and the substrate;
the pixel driving circuit is disposed in the driving layer;
the light-emitting layer is provided with light-emitting elements;
one light-emitting element is electrically connected to one corresponding pixel driving circuit; and
the monitoring unit is at least partially located in the driving layer.

12. The display panel according to claim 11, wherein:
the first driving circuit is located in the driving layer;
the conductive unit is located on a side of the first driving circuit away from the substrate; and
along a direction perpendicular to the plane where the display panel is located, one conductive unit and one corresponding light-emitting element do not overlap.

13. The display panel according to claim 12, wherein:
the conductive unit and the corresponding light-emitting element are disposed in a same layer.

14. The display panel according to claim 12, wherein:
the conductive unit is located on a side of the corresponding light-emitting element facing the first driving circuit.

15. The display panel according to claim 11, wherein:
the light-emitting elements are Micro-LED devices.

16. The display panel according to claim 1, wherein:
the first driving circuit includes a switch transistor;
the switch transistor is a low-temperature polysilicon transistor; and
in the switch transistor, a gate is electrically connected to a first control line, a first electrode is electrically connected to a first data terminal, and a second electrode is electrically connected to the conductive unit.

17. The display panel according to claim 16, wherein:
gates of the switch transistors in the plurality of first driving circuits are all electrically connected to the same first control line, and the first electrodes of the switch transistors are all connected to the same first data terminal.

18. The display panel according to claim 16, wherein:
the pixel area also includes a light-emitting element and a pixel driving circuit connected to the light-emitting element;
the pixel driving circuit includes at least one low-temperature polysilicon transistor;
the switch transistor in the first driving circuit is manufactured simultaneously with the low-temperature polysilicon transistor in the pixel driving circuit.

19. The display panel according to claim 18, wherein:
working phases of the pixel driving circuit include a reset phase, a data writing phase and a light-emitting phase; and
working phases of the first driving circuit include a temperature monitoring phase; and
the temperature monitoring phase does not overlap with the light-emitting phase.

20. The display panel according to claim 1, further including a control chip, wherein:
the signal detection module is integrated into the control chip, and two terminals of the conductive unit are electrically connected to the signal detection module through signal wiring.

21. The display panel according to claim 1, further including a control chip, wherein:
when the signal detection module detects that the voltage or current value at two terminals of the monitoring unit exceeds a preset value, the control chip adjusts data voltage provided to the pixel corresponding to the monitoring unit.

22. A display device comprising a display panel and a driving circuit, wherein:
the display panel includes a display area and a signal detection module;
the display area includes a plurality of pixel areas;
one pixel area of the plurality of pixel area includes at least one pixel and a monitoring unit;
the monitoring unit includes a conductive unit;
the conductive unit includes a low-temperature polysilicon material; and/or the monitoring unit includes a first driving circuit;
the first driving circuit includes at least one low-temperature polysilicon transistor; and
the signal detection module is used to detect a signal on at least one terminal of the monitoring unit.
